(19) United States
(12) Patent Application Publication
(10) Pub. No.: US 2022/0231177 A1
(43) Pub. Date: Jul. 21, 2022

(54) PHOTODIODE WITH IMPROVED RESPONSIVITY

(71) Applicant: SEMICONDUCTOR COMPONENTS INDUSTRIES, LLC, Phoenix, AZ (US)

(72) Inventor: Amit PAUL, Sunnyvale, CA (US)

(73) Assignee: SEMICONDUCTOR COMPONENTS INDUSTRIES, LLC, Phoenix, AZ (US)

(21) Appl. No.: 17/248,307

(22) Filed: Jan. 19, 2021

(51) Int. Cl. H01L 31/0232; H01L 31/0224; H01L 31/18

(52) U.S. Cl. CPC H01L 31/02327; H01L 31/186; H01L 31/022408

(57) ABSTRACT

A photodetector includes a light collection region disposed on a top surface of a semiconductor substrate above a depletion region in the semiconductor substrate, and an arrangement of optical scattering elements disposed in the light collection region. The optical scattering elements scatter light incident along a perpendicular to the light collection region to transit through the depletion region at non-zero angles to the perpendicular.

### TECHNICAL FIELD

This description relates to semiconductor opto-electronic devices.

### BACKGROUND

A photodiode is a semiconductor device with a p-n junction that converts photons (or light) into electrical current. Photodiodes can be manufactured from a variety of materials including, but not limited to, Silicon, Germanium, and Indium Gallium Arsenide. Each material uses different properties for, for example, cost benefit, increased sensitivity, wavelength range, low noise levels, or even response speed.

### SUMMARY

A device includes a depletion region formed between a p-doped region and a n-doped region in a semiconductor substrate. A light collection region disposed on a top surface of the semiconductor substrate above the depletion region, and an optical scattering element is disposed in the light collection region. The optical scattering element deflects a light photon incident on the light collection region to transit through the depletion region at a non-zero angle to a normal to the light collection region.

A method includes disposing an anode terminal and a cathode terminal on a photodiode for applying a bias voltage across the photodiode to maintain a depletion region in the photodiode, and disposing at least one optical scattering element in the photodiode. The at least one optical scattering element scatters light incident on the photodiode to transit the depletion region at a non-zero angle to a normal direction of the photodiode.

The details of one or more implementations are set forth in the accompanying drawings and the description below. Other features will be apparent from the description and drawings, and from the claims.

### BRIEF DESCRIPTION OF THE DRAWINGS

FIG. 1 illustrates, a cross sectional view, of an example photodiode.

FIG. 2A illustrates an example photodiode that includes an arrangement optical scattering elements.

FIG. 2B illustrates a portion of the photodiode of FIG. 2A with optical scattering elements made of polysilicon.

FIG. 2C illustrates an enlarged view of a portion of the photodiode of FIG. 2B.

FIGS. 3A and 3B illustrate example device layouts of a photodiode including arrangements of optical scattering elements.

FIGS. 3C through 3E illustrate example device layouts of a photodiode including arrangements of optical scattering elements shaped as lines of material.

FIG. 3F illustrates an example device layout of a photodiode in which an optical scattering element is a hole in a dielectric layer.

FIG. 4 illustrates an example method for improving the spectral sensitivity or responsivity of a photodiode.

### DETAILED DESCRIPTION

A photodetector (e.g., a photodiode) is a semiconductor device with a p-n junction that converts incident light (photons) into electrical current. The terms light and photons may be used interchangeably herein. The p-n junction is formed between a p-doped region and a n-doped region in a semiconductor substrate. A depletion region in which no free carriers exist is formed about the p-n junction by diffusion of electrons from the n-doped region to the p-doped region and the diffusion of holes from the p-doped region to the n-doped region. A built-in junction voltage creates an electric field across the depletion region allowing current to flow only in one direction (e.g., anode to cathode). across the p-n junction. Light or photons absorbed in the depletion region (or close to it) can create electron hole pairs that will move to opposite ends of the photodiode due to the electric field. Electrons, for example, will move toward a positive potential on a cathode of the photodetector, and the holes will move toward a negative potential on an anode of the photodetector. These moving charge carriers (i.e., electrons and holes) form the current (photocurrent) in the photodetector (e.g., photodiode). A figure of merit of photodetector performance is spectral sensitivity or responsivity R. In case of a photodiode, responsivity R measures the electrical output per optical input. The responsivity of a photodetector is usually expressed in units of either amperes or volts per watt of incident radiant power. Responsivity is a function of the wavelength of the incident radiation and of the photodetector properties, such as the bandgap of the material of which the photodetector is made as well as the externally applied bias. An expression for the responsivity R of a photodetector in which incident light is converted into an electric current (known as a photocurrent) is R=η Q h f=ηλ (μm) 1.23985 (μm×W/A), whereη is the a quantum efficiency (the conversion efficiency of a photon to an electron) of the photodetector for a given wavelength, is the electron charge, is the frequency of the incident light (optical signal), and is Planck's constant. R has units of amperes per watt (A/W). A responsivity curve of a photodetector may show A/W as a function of wavelength.

The quantum efficiency η of a photodetector is the probability that a single light photon incident on the device generates a photocarrier pair (i.e., electron hole pair) that contributes to the detector current. The quantum efficiency rₗ depends on the distance in the depletion region traversed by the single photon. The spectral sensitivity or responsivity R of a photodetector depends on a width of the depletion region and a horizontal surface area (i.e., a horizontal size of photodiode) of a light-receiving region of the photodetector over which the light photons are incident as well as the depth of the depletion region below the semiconductor surface.

Photodetectors (e.g., photodiodes) are used in a variety of different circuits to convert incident optical signals into electrical current or voltage signals. A photodetector may, for example, be deployed in an opto-coupler to galvanically isolate low-voltage and high-voltage sides of a circuit by using a light emitter (e.g., a light emitting diode (LED)) to transmit a control signal (incident light signal) to the photodetector and reduce electrical noise coupling. In example implementations, a high voltage opto-coupler circuit may use, for example, infrared wavelengths in a range of about 800 to 900 nm for the control signal. A large area photodetector (photodiode) may be needed to generate a required photocurrent for control signals in the infrared range of about 800 to 900 nm, and for the circuit topology used. In some process technologies, a photodiode size may be on the order of 400 μm×400 μm or larger in size. The photodiode area may be 15% or higher of a total die area of the opto-coupler circuit.

The disclosure herein describes photodiode structures and techniques for improving or increasing the responsivity of photodiodes. Improving or increasing the responsivity of photodiodes may enable reduction in the size of the photodiodes needed for circuit applications (e.g., for opto-couplers and other types of circuits).

Optical scattering elements are integrated in light-receiving regions of the photodiode structures, in accordance with the principles of the present disclosure. The optical scattering elements can deflect (e.g., scatter, refract, or diffract) normally incident light photons to propagate at different scattering angles θ to the normal (e.g., non-zero forward scattering angles θ greater than 0° and up to90°) through the electron-hole pair-generating depletion region of the photodiode. Photons that propagate geometrically at the different angles θ have a longer path length through the electron-hole pair-generating depletion region of the photodiode, and can result in more electron-hole pairs being generated per photon than for the normally incident photons (in other words, the quantum efficiency of the photodetector is increased).

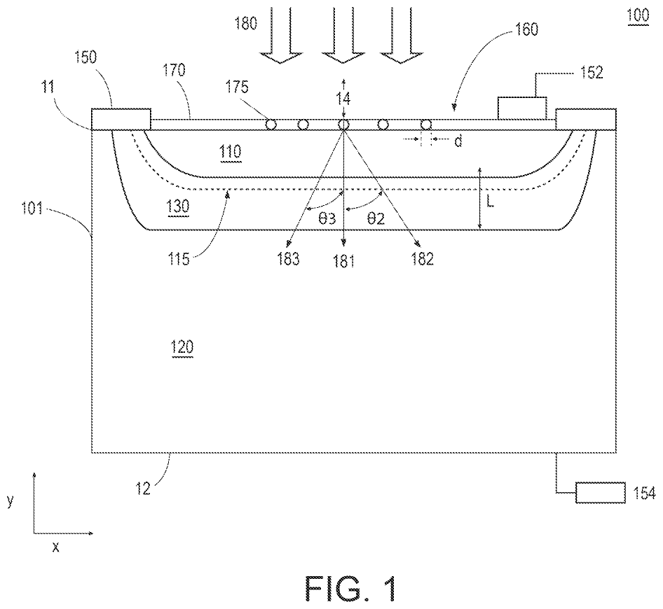

FIG. 1 schematically shows, in a cross sectional view, an example photodiode 100 with optical scattering elements 175 disposed in a light-receiving region of the photodiode, in accordance with the principles of the present disclosure.

Photodiode 100 may be fabricated on a semiconductor substrate 101 (e.g., a p-type silicon substrate). A n-doped region (e.g., n-doped region 110) may be formed in substrate 101, for example, by thermal diffusion or ion implantation of a n-type dopant (e.g., phosphorus) in substrate 101. Photodiode 100 may include a p-n junction 115 formed between a n-doped region 110 and a p-doped region 120 (e.g., a region of the bulk substrate). A depletion region 130 may form near p-n junction 115. A front surface 11 and a back surface 12 of photodiode 100 may be connected to cathode and anode terminals of the photodiode (e.g., an anode terminal 154 and a cathode terminal 152). The terminals may be used, for example, to apply a voltage to reverse bias p-n junction 115. Depletion region 130 may have a width or thickness L (e.g., in a vertical direction 14 along the y axis) perpendicular or normal to front surface 11 of the photodiode). Reverse biasing p-n junction 115 may, for example, increase the width or thickness L of depletion region 130.

Front surface 11 of photodiode 100 may include a light-collection region (e.g., an active area 160) over which light photons 180 can be incident on photodiode 100. Front surface 11 may include dielectric structures 150 (e.g., silicon dioxide) that may be used, for example, as diffusion masks when forming p-doped region 110 below active area 160 or forming other device elements. Further, active area 160 may be covered by a dielectric layer 170 (e.g., a passivating layer, an anti-reflection (AR) coating, etc.). Light photons 180 incident on active area may pass through dielectric layer 170 into depletion region 130. Light photons 180 absorbed or transiting through depletion region 130 can generate electron-hole pairs for a photocurrent. The generated photocurrent may be proportional to the quantum efficiency of the photons (i.e., a number of electron hole pairs generated by a light photon as the light photon traverses the depletion region) in photodiode 100. For a photon traversing depletion region 130 normally (e.g. perpendicular to surface 11) the quantum efficiency of the photons may be proportional to the width of thickness L of the depletion region. In FIG. 1, a photon traversing the depletion region 130 normally is depicted by arrow 181.

In accordance with the principles of the present disclosure, optical scattering element 175 are disposed in active area 160, for example, in the path of normally incident light (incident light photons 180). Optical scattering elements 175 may, for example, be disposed on, or included in, layer 170 covering active area 160. Optical scattering elements 175 may be opaque (metallic) or semi-transparent structures (e.g., oxides, nitrides, etc.) that can scatter or diffract normally incident light photons 180 at a scattering angle (e.g., an angle θ greater than 0° and up to 90°) to the normal. Optical scattering elements 175 may be additive structures (e.g., particles) or subtractive structures (e.g., holes) formed in the metallic or non-metallic layers. The metallic or non-metallic layers may be formed of opaque or semi-transparent materials. Example non-metallic materials may include dielectric material (such as silicon oxide or silicon nitride) or semiconductor materials. Optical scattering elements 175 may have dimensions of a few to several hundreds of nanometers (e.g., 100 nm to 7000 nm). In example implementations, optical scattering elements 175 may have dimensions that are larger than the wavelength of incident light photons 180.

In example implementations, for example, for high voltage opto-coupler applications, light photons 180 that are incident on active area 160 of photodiode 100 may, for example, be in an infrared range of wavelengths (e.g., 800 nm−900 nm).

FIG. 1 shows, for example, a normally incident photon (e.g., depicted by an arrow 181) transiting through depletion region 130 may have a transit path length that corresponds to the width or thickness L of depletion region 130. Further, incident light photons 180 (depicted by arrows 182 and 183) that may be scattered by optical scattering elements 175 (as depicted by arrows 182 and 183) to propagate at an angle (e.g., angle θ2 or θ3) to the normal through depletion region 130. Incident light photons 180 that propagate at an angle (e.g., angles θ2 and θ3) to the normal through depletion region 130 have a longer (i.e., increased) transit path in the depletion region compared to the transit path length L of the normally incident photon (e.g., arrow 181). The increase in the transit path length for a photon scattered at angle may be geometrically proportional to the inverse cosine function cos⁻¹ (θ) (which always has a numerical value greater than 1). The increase in the transit path length may be visualized, for example, by visual comparison of the length of arrow 181 and the lengths of arrows 182 or 183 shown in FIG. 1.

The increase in the length of transit path of scattered photons through the depletion region can increase the quantum efficiency of incident photons and the spectral sensitivity or responsivity R of photodiode 100.

In example implementations, optical scattering elements 175 may be formed by patterning a metal layer or a dielectric layer placed over the photodiode active area during device fabrication. While optical scattering elements 175 may scatter light, optical scattering elements 175 may not have any electrical effect or function in photodiode 100.

In example implementations, an arrangement or pattern of optical scattering elements 175 may be disposed in an light-collection region (active region) of a photodiode. In some implementations, the photodiode (like photodiode 100 shown in FIG. 1) may have a p-n junction formed by diffusing a n-region in an p-type substrate. In other implementations, the photodiode may have a p-n junction formed by diffusing a p-region in a n-type substrate.

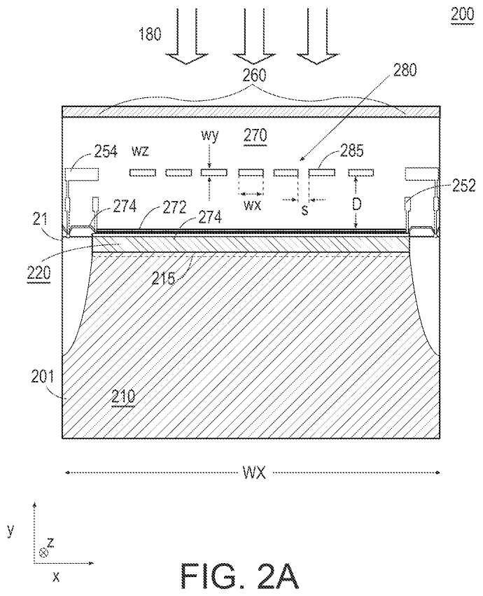

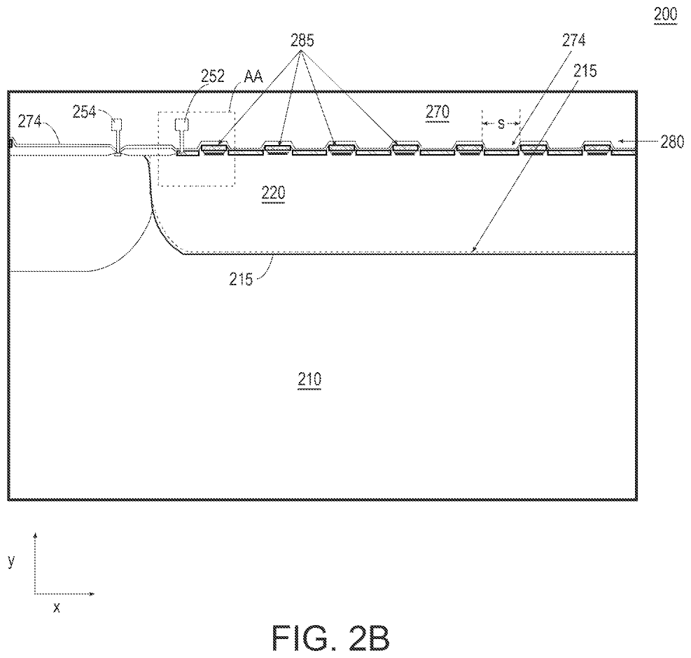

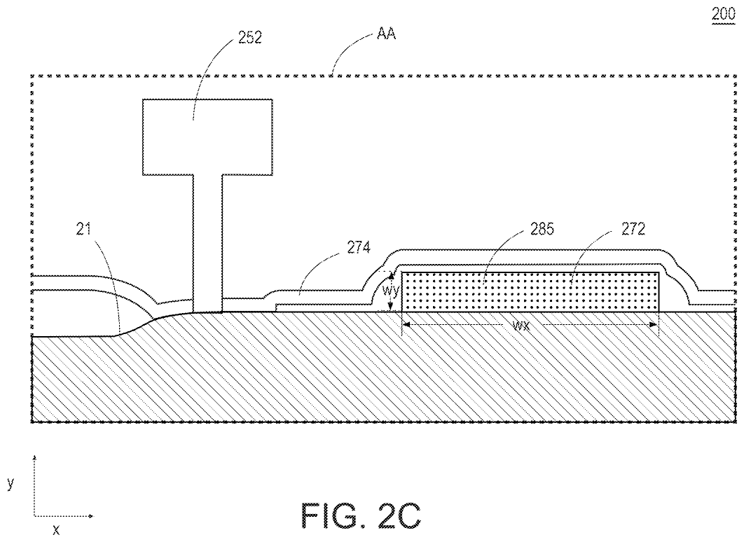

FIG. 2A shows a cross-sectional view of an example photodiode 200 that includes an arrangement 280 of optical scattering elements (e.g., optical scattering elements 285) for intercepting and scattering light photons incident on its light collection region (e.g., active area 260), in accordance with the principles of the present disclosure.

As seen in FIG. 2A, example photodiode 200 (having a width WX in the x-direction) may be formed in a p-type semiconductor substrate 201. Photodiode 200 includes a p-n junction 215 formed in p-type semiconductor substrate 201 between a p-type region 210 and a n-type region 220 (e.g., a diffused n-type region). A top surface 21 of substrate 201 may be covered by one or more passivating, isolating, and antireflection (AR) coating dielectric layers. The passivating, isolating, or antireflection (AR) coating dielectric layers may, for example, include one or more of silicon dioxide, silicon nitride, silicon oxy-nitride (SiON), polyimide, spin on glass, and fluoridated silicon dioxide layers.

Metal contacts (e.g., anode contact 254, and cathode contact 252) to the device may be disposed on top surface 21 of substrate 201. A dielectric layer 272 (e.g., a polysilicon layer and or a silicon nitride layer) may be disposed on top surface 21 of substrate 201. An etch stop layer 274 (e.g., a SiON layer) may be disposed over dielectric layer 272 on top surface 21 of substrate 201. Further, a dielectric layer 270 (e.g., an oxide layer) may overlay photodiode 200 (enclosing or covering anode contact 254, cathode contact 252, dielectric layer 272, and etch stop layer 274 that may be disposed on top surface 21 of substrate 201).

An arrangement 280 of optical scattering elements 285 for scattering light photons (e.g., incident light photons 180) incident on light collection region (e.g., active area 260) may be disposed on surface 21, on dielectric layer 270, or included in dielectric layer 270.

In some example implementations, optical scattering elements 285 may be metal or metallic objects embedded in dielectric layer 270 (e.g., an oxide layer). The metal or metallic objects may, for example, be made of copper, aluminum, tungsten, and a metal alloy, etc. In example implementations, as shown in FIG. 2A, an optical scattering element 285 may be a rectangular metal segment with a height wy, a width wx (and a depth wz (not shown) in a z direction perpendicular to the page of the figure). In example implementations, height wy may, for example, be in a range of 200 nm to 1000 nm, and width wx and depth wz may, for example, each be in a range of 200 nm to 3000 nm.

In some example implementations, optical scattering elements 285 may be made of dielectric material (e.g., poly silicon, silicon nitride, etc.). Optical scattering elements 285 may, for example, be polysilicon segments that are patterned and embedded, for example, in dielectric layer 272 disposed on surface 21 of the substrate. FIG. 2B shows a portion of photodiode 200 to illustrate optical scattering elements (e.g., optical scattering elements 285) made of polysilicon, and FIG. 2C shows an exploded view of portion AA of photodiode 200 shown in FIG. 2B to further illustrate an individual polysilicon segment used as optical scattering element 285.

In example implementations, as shown in FIG. 2B and FIG. 2C, an optical scattering element 285 may be a rectangular polysilicon segment with a height wy, a width wx (and a depth wz (not shown) in a z direction perpendicular to the page of the figure). In example implementations, height wy may, for example, be in a range of 100 nm to 1000 nm, and each of width wx and depth wz may, for example, be in a range of 200 nm to 3000 nm.

Optical scattering elements 285 may be disposed in arrangement 280 in photodiode 200 (FIG. 2A, 2B and 2C), for example, with a same inter-element spacing s between each neighboring pair of the elements. In other words, optical scattering elements 285 may be distributed evenly (i.e., evenly spaced or regularly spaced in a periodic pattern) in arrangement 280 (as shown in FIG. 2A). In other example implementations, optical scattering elements 285 may be distributed unevenly (e.g., with varying or staggered inter-element spacings s) in arrangement 280.

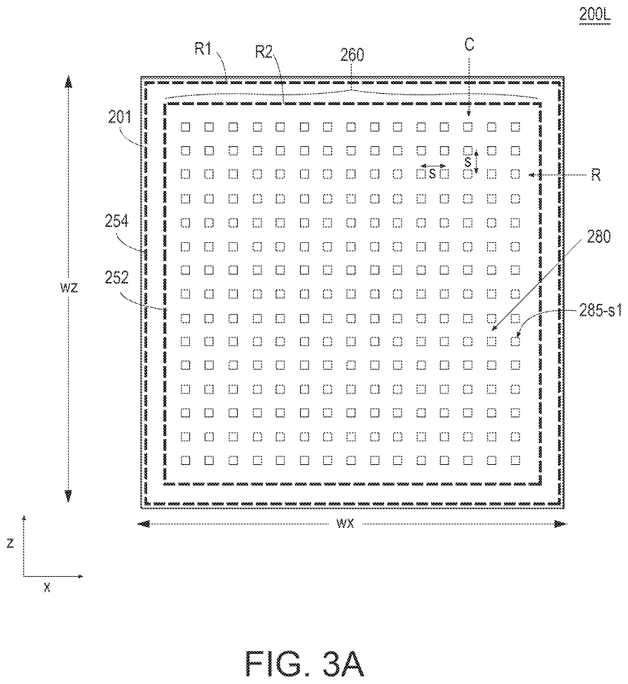

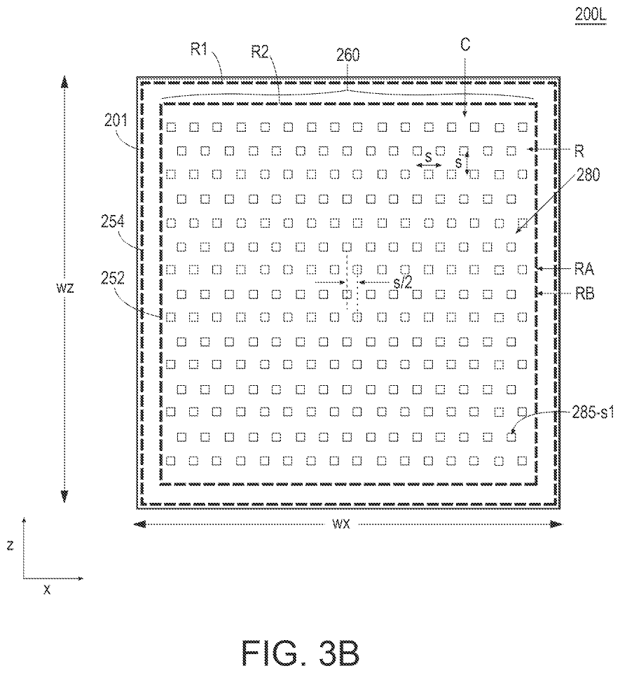

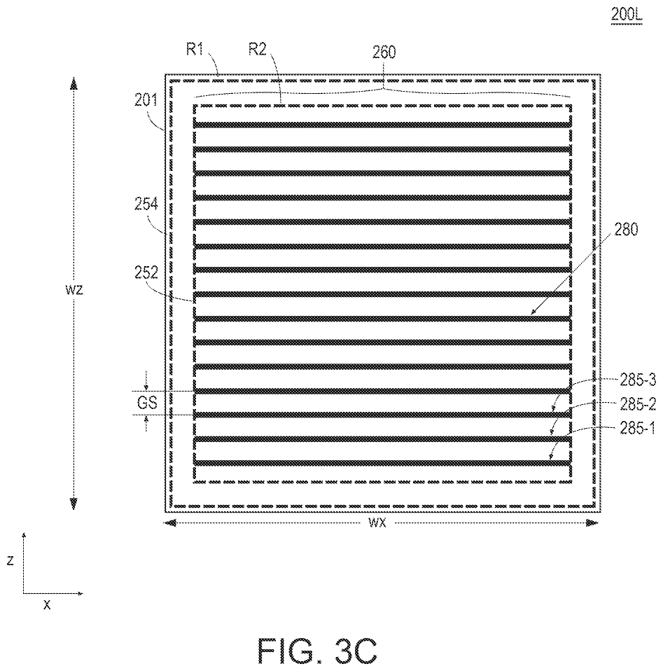

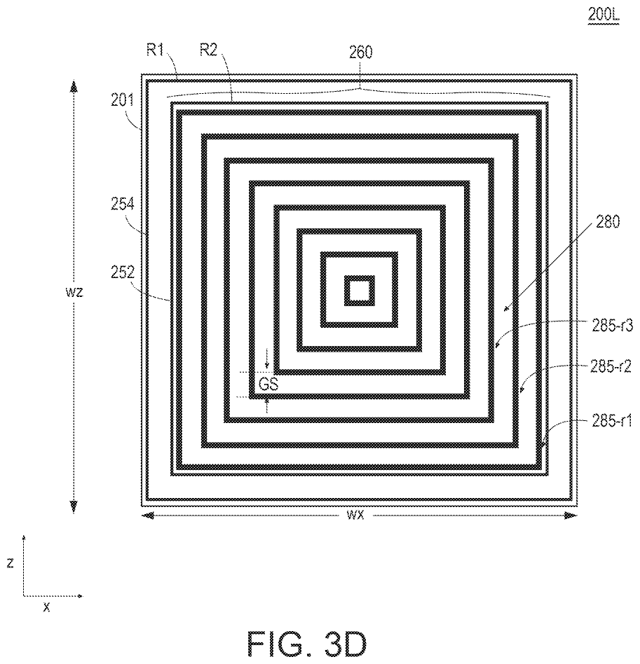

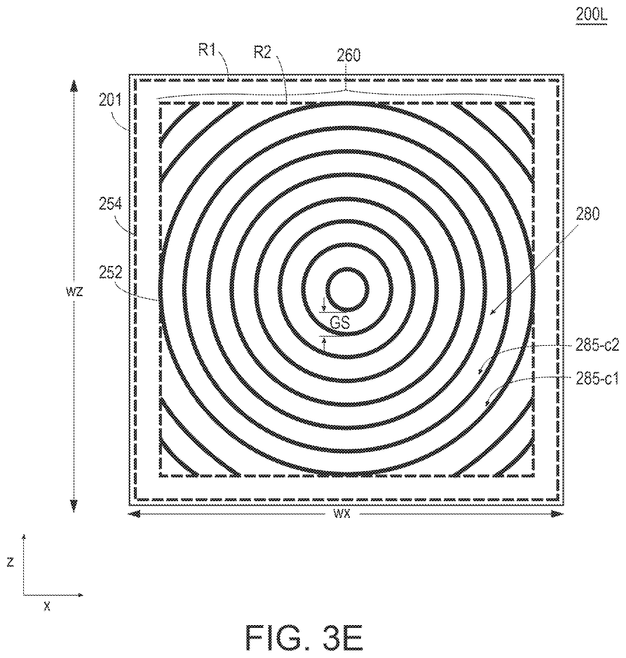

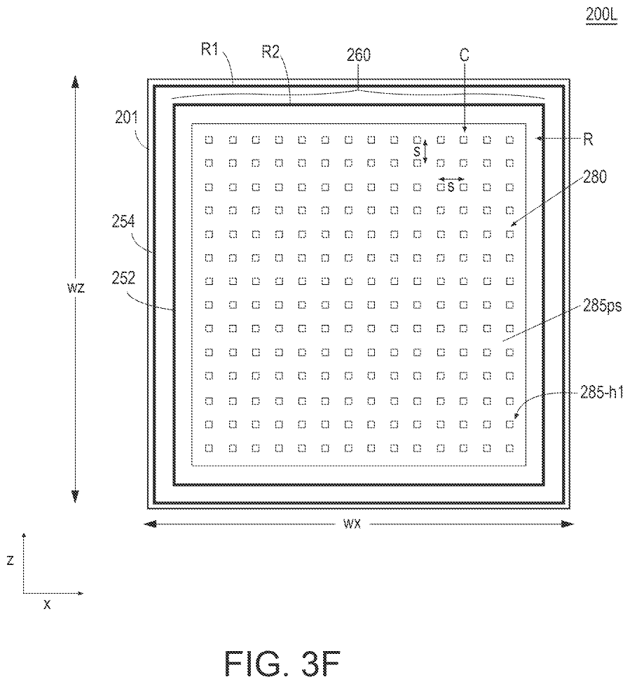

FIGS. 3A and FIG. 3B show example device layouts 200L of photodiode 200 (e.g., photodiode 200 with optical scattering elements 285 made of metal as shown in FIG. 2A, or photodiode 200 with optical scattering elements 285 made of metal as shown in FIG. 2B).

As shown in FIGS. 3A and 3B, photodiode 200, which may be formed on substrate 201, may have a rectangular (or square) shape with sides having a dimension WX in the x direction and a dimension WZ in the z-direction.

Further, anode contact 254 and cathode contact 252 may be disposed as concentric rectangles R1 and R2 on substrate 201 in device layout 200L. The inner concentric rectangle R2 (cathode contact 252) may enclose or define a light collection region (active area 260) of photodiode 200. Further, arrangement 280 of optical scattering elements 285 for scattering light incident on the active area 260 may be placed within the inner concentric rectangle R2 of cathode contact 252.

In the examples shown in FIG. 3A and FIG. 3B, arrangement 280 may include optical scattering elements 285 arranged in a rectangular (or square) geometrical pattern in which the optical scattering elements 285 are placed on a rectangular or square x-z lattice. As shown, for example, in FIG. 3A, the optical scattering elements 285 may be placed evenly in rows R and columns C of the lattice with a same inter-element spacing s in both the x direction and in the z direction.

As shown, for example, in FIG. 3B, optical scattering elements 285 placed in a row (e.g., row RA) on the rectangular or square x-z lattice may be offset in the x direction (e.g., by a distance s/2) relative to the positions of optical scattering elements 285 placed in an alternate row (e.g., row RB).

In other example implementations, arrangement 280 may include other shapes and geometrical patterns of the optical scattering elements.

FIGS. 3D through 3F show example device layouts 200L of photodiode 200 with different shapes and geometrical patterns of the optical scattering elements in arrangement 280 disposed on top surface 21 of substrate 201.

In example implementations, the optical scattering elements may be shaped from lines of material (e.g., additive metal or dielectric material objects, or subtractive holes in dielectric layers)) that are further shaped to form outlines of other shapes (e.g., rectangles, squares, circles, ovals, etc.). In some instances, the lines of material may include additive metal or dielectric material objects. In some instances, the lines of material may be subtractive material objects (e.g., holes in a dielectric layer).

In example implementations, the lines of material may be disposed on, or embedded in, dielectric layers (e.g., dielectric layers 270 or 272) disposed on top surface 21 of substrate 201.

FIG. 3C shows an example arrangement 280 including optical scattering elements shaped as lines of material (e.g., optical scattering elements 285-1, 285-2, 285-3, etc.). In the example shown in FIG. 3C, the lines of material (e.g., optical scattering elements 285-1, 285-2, 285-3, etc.) may be straight lines extending (e.g., in the x-direction) across inner concentric rectangle R2 (cathode contact 252) that encloses or defines the light collection region (active area 260) of photodiode 200. The straight lines of material (e.g., optical scattering elements 285-1, 285-2, 285-3, etc.) may be disposed in a repeating pattern in arrangement 280 with an inter-line spacing GS in a vertical direction (e.g., in the z direction).

FIG. 3D, like FIG. 3C, shows an example arrangement 280 including optical scattering elements shaped as lines of material (e.g., optical scattering elements 285-r1, 285-r2, 285-r3, etc.). In the example shown in FIG. 3D, the lines of material may form rectangles that may be disposed as a pattern of concentric rectangles (with an inter-rectangle spacing GS) within the inner concentric rectangle R2 (cathode contact 252) that encloses or defines the light collection region (active area 260) of photodiode 200.

FIG. 3E, like FIG. 3C, shows an example arrangement 280 including optical scattering elements shaped as lines of material (e.g., optical scattering elements 285-c1, 285-c2, etc.). In the example shown in FIG. 3E, the lines of material may form circles that may be disposed as a pattern of concentric circles (with an inter-circle spacing GS) within the inner concentric rectangle R2 (cathode contact 252) that encloses or defines the light collection region (active area 260) of photodiode 200.

In example implementations, the optical scattering elements may be shaped from lines of material (e.g., additive metal or dielectric material objects, or subtractive holes in dielectric layers)) that are further shaped to form outlines of other shapes (e.g., rectangles, squares, circles, ovals, etc.).

In an example implementation, an optical scattering element may be a subtractive material object (e.g., a hole in a dielectric layer).

FIG. 3F shows an example arrangement 280 in which an optical scattering element (e.g., optical scattering element 285-h1) is a hole in a dielectric layer (e.g., polysilicon layer 285ps). The hole may have any shape (e.g., rectangle, square, circle, oval, etc.). The dielectric layer may include materials (e.g., polysilicon, silicon nitride, etc.) which may be transparent, or at least partially transparent, to light, for example, at infrared wavelengths. The dielectric layer (e.g., polysilicon layer 285ps) may be disposed on top surface 21 of substrate 201. The hole (e.g., optical scattering element 285-h1) may have any shape (e.g., rectangle, square, circle, oval, etc.).

In the example shown in FIG. 3G, arrangement 280 may include optical scattering elements 285-h1 (holes) arranged in a rectangular or square geometrical pattern (like the optical scattering elements 285 in FIG. 3A). Optical scattering elements 285-h1 may be placed in rows and columns on a rectangular or square x-z lattice. The optical scattering elements 285-h1 may be placed evenly in rows R and columns C of the lattice with a same inter-element spacing s in both the x direction and in the z direction.

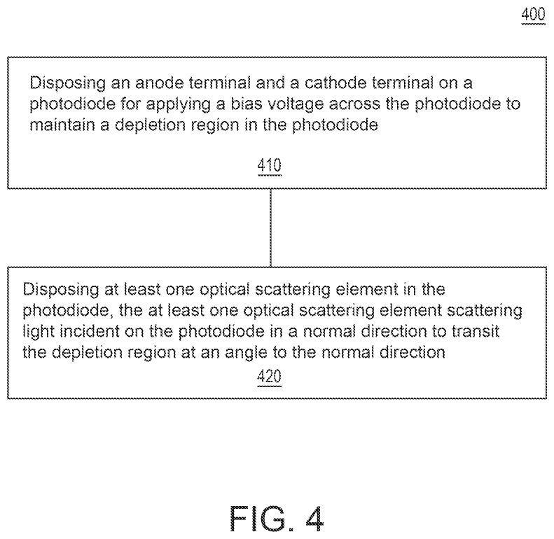

FIG. 4 illustrates an example method 400 for improving the spectral sensitivity or responsivity of a photodiode. The photodiode may be a semiconductor device that includes a light collection region (i.e., an active area) on which light photons can be incident for conversion into a photocurrent. The light photons transiting through a depletion region in the photodiode can generate electron-hole pairs for the photocurrent.

Method 400 includes disposing an anode and a cathode for applying a bias voltage to maintain a depletion region in the diode (410); and disposing at least one optical scattering element in the diode, the at least one optical scattering element scattering light incident on the diode in a normal direction to transit the depletion region at an angle to the normal direction.

It will be understood that, in the foregoing description, when an element, such as a layer, a region, a substrate, or component is referred to as being on, connected to, electrically connected to, coupled to, or electrically coupled to another element, it may be directly on, connected or coupled to the other element, or one or more intervening elements may be present. In contrast, when an element is referred to as being directly on, directly connected to or directly coupled to another element or layer, there are no intervening elements or layers present. Although the terms directly on, directly connected to, or directly coupled to may not be used throughout the detailed description, elements that are shown as being directly on, directly connected or directly coupled can be referred to as such. The claims of the application, if any, may be amended to recite exemplary relationships described in the specification or shown in the figures.

As used in the specification and claims, a singular form may, unless definitely indicating a particular case in terms of the context, include a plural form. Spatially relative terms (e.g., over, above, upper, under, beneath, below, lower, and so forth) are intended to encompass different orientations of the device in use or operation in addition to the orientation depicted in the figures. In some implementations, the relative terms above and below can, respectively, include vertically above and vertically below. In some implementations, the term adjacent can include laterally adjacent to or horizontally adjacent to.

Some implementations may be implemented using various semiconductor processing and/or packaging techniques. Some implementations may be implemented using various types of semiconductor processing techniques associated with semiconductor substrates including, but not limited to, for example, Silicon (Si), Silicon Germaniums (SiGe), Germanium (Ge), Gallium Arsenide (GaAs), Gallium Nitride (GaN), Silicon Carbide (SiC) and/or so forth.

While certain features of the described implementations have been illustrated as described herein, many modifications, substitutions, changes and equivalents will now occur to those skilled in the art. It is, therefore, to be understood that the appended claims are intended to cover all such modifications and changes as fall within the scope of the implementations. It should be understood that they have been presented by way of example only, not limitation, and various changes in form and details may be made. Any portion of the apparatus and/or methods described herein may be combined in any combination, except mutually exclusive combinations. The 7implementations described herein can include various combinations and/or sub-combinations of the functions, components and/or features of the different implementations described.

For example, a photodiode fabricated on a n-type substate will have opposite types of doped regions than a photodiode fabricated on a p-type substrate (in other words, n-type and p-type regions in the photodiode fabricated on the n-type substate may respectively correspond to p-type and n-type regions in the photodiode fabricated on the p-type substrate). While incorporation of optical scattering elements in the light collection regions of photodiodes has been described herein using, for example, photodiodes fabricated on p-type substrates (e.g., p-type substate 101, FIG. 1, and p-type substrate 210, FIGS. 2A through 3F), the disclosed principles of incorporating optical scattering elements in the light collection region to scatter incident light through the photodiode's depletion region are also applicable to photodiodes fabricated on n-type substrates.

What is claimed is:

1. A device comprising:
a depletion region formed between a p-doped region and a n-doped region in a semiconductor substrate;
a light collection region disposed on a top surface of the semiconductor substrate above the depletion region; and
an optical scattering element disposed in the light collection region, the optical scattering element deflecting a light photon incident on the light collection region to transit through the depletion region at a non-zero angle to a normal to the light collection region.

2. The device of claim 1, wherein the light collection region includes a silicon dioxide layer disposed on the top surface of the semiconductor substrate, and wherein the optical scattering element is disposed in the silicon dioxide layer.

3. The device of claim 1, wherein the light collection region includes a dielectric layer disposed on the top surface of the semiconductor substrate above the depletion region, and wherein the optical scattering element is disposed in the dielectric layer.

4. The device of claim 1, wherein the optical scattering element is a metallic object including at least one of copper, aluminum, tungsten, and a metal alloy.

5. The device of claim 1, wherein the optical scattering element is a non-metallic object including at least one of silicon oxide, silicon nitride, and semiconductor material.

6. The device of claim 1, wherein the optical scattering element is a hole formed in a dielectric layer.

7. The device of claim 1, wherein the optical scattering element is transparent, or at least partially transparent, to light having a wavelength in a range of about 800 to 900 nanometers.

8. The device of claim 1, wherein the optical scattering element has a height, a width, and a depth, and wherein the height is in a range of about 200 nm to 1000 nm, and the width and the depth are each in a range of about 200 nm to 3000 nm.

9. The device of claim 1, wherein the optical scattering element is disposed above the top surface at a vertical distance perpendicular to the top surface, and the vertical distance is in in a range of about 0 nm to 3000 nm.

10. The device of claim 1, further comprising:
an anode terminal and a cathode terminal on the device for applying a bias voltage to maintain a depletion region in the device.

11. A photodetector comprising:
a light collection region disposed on a top surface of a semiconductor substrate above a depletion region in the semiconductor substrate; and
an arrangement of optical scattering elements disposed in the light collection region, the optical scattering elements scattering light incident along a perpendicular to the light collection region to transit through the depletion region at non-zero angles to the perpendicular.

12. The photodetector of claim 11, wherein the arrangement of optical scattering elements includes at least one optical scattering element having a height, a width, and a depth, and wherein the height is in a range of about 200 nm to 1000 nm, and the width and the depth are each in a range of about 200 nm to 3000 nm.

13. The photodetector of claim 11, wherein the arrangement of optical scattering elements includes at least one optical scattering element made of metal or a metal alloy.

14. The photodetector of claim 11, wherein the arrangement of optical scattering elements includes at least one optical scattering element made of a dielectric material.

15. The photodetector of claim 11, wherein the arrangement of optical scattering elements includes an optical scattering element that is a hole in a dielectric layer.

16. The photodetector of claim 11, wherein the arrangement includes optical scattering elements disposed in a rectangular or square geometrical pattern with the optical scattering elements placed in rows and columns of a rectangular or square lattice.

17. The photodetector of claim 16, wherein the optical scattering elements are disposed in the rows and the columns of the rectangular or square lattice with about a same inter-element spacing in both the rows and the columns.

18. The photodetector of claim 11, wherein the optical scattering elements are lines of material, and wherein the lines of material are disposed in the light collection region in a geometrical pattern, the geometrical pattern including at least a pattern of a group of straight lines, a pattern of the lines of material grouped as concentric circles, and a pattern of the lines of material grouped as concentric squares or rectangles.

19. A method, comprising:
disposing an anode terminal and a cathode terminal on a photodiode for applying a bias voltage across the photodiode to maintain a depletion region in the photodiode; and
disposing at least one optical scattering element in the photodiode, the at least one optical scattering element scattering light incident on the photodiode to transit the depletion region at a non-zero angle to a normal direction of the photodiode.

20. The method of claim 19, wherein disposing at least one optical scattering element in the photodiode includes disposing at least one of a metallic object and a non-metallic object in the photodiode to scatter light incident on the photodiode.
